(19) United States
(12) Patent Application Publication
(10) Pub. No.: US 2024/0274313 A1
(43) Pub. Date: Aug. 15, 2024

(54) STRUCTURES FOR PATTERNING SUBSTRATES AND METHODS AND SYSTEMS FOR THEIR MANUFACTURE

(71) Applicant: ASM IP Holding B.V., Almere (NL)

(72) Inventors: Fatemeh Davodi, Helsinki (FI); Steaphan Wallace, Leuven (BE); Yoann Tomczak, Leuven (BE); David Kurt de Roest, Leuven (BE)

(21) Appl. No.: 18/431,164

(22) Filed: Feb. 2, 2024

Related U.S. Application Data
(60) Provisional application No. 63/484,346, filed on Feb. 10, 2023.

(51) Int. Cl. G21K 1/06; G03F 7/00; G03F 7/11; H01J 37/32

(52) U.S. Cl. CPC G21K 1/06; G03F 7/0035; G03F 7/11; G03F 7/70033; G03F 7/7075; H01J 37/32146; H01J 2237/332

(57) ABSTRACT

Structures, related methods, and related systems for reducing EUV dose. A structure as described herein can comprise a substrate; an electron reflector layer overlying the substrate; and, an extreme ultraviolet (EUV) resist overlying an electron generation layer. The EUV resist is constructed and arranged for absorbing EUV radiation and generating secondary electrons. The electron reflector layer is constructed and arranged for reflecting secondary electrons generated by the EUV resist back towards the EUV resist.

### CROSS-REFERENCE TO RELATED APPLICATION(S)

This Application claims the benefit of U.S. Provisional Application No. 63/484,346 filed on Feb. 10, 2023, the entire contents of which are incorporated herein by reference.

### FIELD OF INVENTION

The present disclosure is in the field of integrated circuit manufacture, in particular in the field of Front-end-of-Line Patterning, more particular in the field of extreme ultraviolet (EUV) patterning.

### BACKGROUND OF THE DISCLOSURE

Semiconductor device patterning is often designed around the properties of expensive lithography equipment. Reducing the time needed per wafer during lithography steps can greatly improve throughput and costs of device fabrication, and this time can be expressed in terms of lithography dose.

In the emerging field of extreme ultraviolet (EUV) lithography, which improves resolution through decreased wavelength, the energy per photon is greatly increased. To reduce the dose, either the photon flux or the exposure time needs to be decreased, both of which reduces the total number of photons hitting the lithography resists to very low amounts. Moreover, high energy EUV photons are more difficult to absorb by most materials, exaggerating the issue of the low photon count. With such a low amount of photons absorbed by the resist, it is difficult to obtain a good quality lithography structure due to the photon shot noise effect, especially at the small structure sizes being pursued. Therefore, the key to practically decreasing dose is to increase the useful effect of each photon.

The usefulness of each photon may be improved through two ways: by increasing the absorption of each photon, and by increasing the number of electrons produced per photon. Absorption may be improved by inserting EUV absorbing materials into the lithography structure. This absorption produces photoelectrons which can cause reactions in the resist, but one electron per photon conversion still produces high shot noise. This problem is solved if the high energy photoelectrons are converted into multiple secondary electrons (SEs) through multiple possible pathways.

EUV absorbing and SE producing materials may be incorporated into the lithography stack using various ways. One way is to directly add the materials to the resist such as by adding sensitizers to chemically amplified resists (CARs) or by using highly absorbing metal oxide resists (MORs). However, there are drawbacks to these resists. Resists have become complicated structures that are difficult to control SE generation, and too high absorption in the resist can block photons from traveling to the bottom of the resist where needed. Too long of electron path in the resist is also not desired as this will hurt resolution and cause roughness. If absorption is balanced so photons absorb at the resist bottom, SEs are still often lost to the substrate.

Additionally or alternatively, an underlayer containing EUV absorbing and SE producing materials may be employed. Such underlayers can be directly designed to produce many electrons and thereby help to supply SEs to the resist bottom. However, many of the materials are heavy metals with self-limiting effects because electrons from deeper levels cannot easily move to the resist.

Thus, there is a need for improved methods and structures for EUV dose reduction.

### SUMMARY OF THE DISCLOSURE

Described herein are structures, related methods, and related systems, that can be employed for dose reduction in EUV lithography. Structures as described herein comprise an electron reflector layer overlying the substrate. In some embodiments, a structure as described herein comprises a substrate; an electron reflector layer overlying the substrate; and, an extreme ultraviolet (EUV) resist overlying the electron generation layer; wherein, the EUV resist is constructed and arranged for absorbing EUV radiation and generating secondary electrons; and, the electron reflector layer is constructed and arranged for reflecting secondary electrons generated by the EUV resist back towards the EUV resist.

In some embodiments, the electron reflection layer comprises at least one of aluminum and magnesium.

In some embodiments, the electron reflection layer comprises an electron reflection material selected from the list consisting of Al₂O₃, AlN, AlON, and MgAl₂O₄.

In some embodiments, the EUV resist is selected from a metalorganic framework resist, a metal oxide resist, and a chemically amplified resist.

In some embodiments, a structure as described herein further comprises a glue layer.

In some embodiments, the glue layer comprises silicon, oxygen, and carbon.

In some embodiments, the glue layer is positioned between the electron reflector layer and the EUV resist.

In some embodiments, a structure as described herein further comprises an electron generation layer.

In some embodiments, the electron generation layer is positioned between the electron reflector layer and the EUV resist.

In some embodiments, the glue layer is positioned between the electron reflector layer and the EUV resist.

Methods as described herein comprise forming an electron reflector layer on a substrate. In some embodiments, a method as described herein comprises providing a substrate to a reaction chamber; forming an electron reflector layer on the substrate; optionally forming a secondary electron generating layer on the substrate; optionally forming a glue layer on the substrate; and, forming an EUV resist on the substrate; the EUV resist is arranged for absorbing EUV radiation and generating secondary electrons; the electron reflector layer is constructed and arranged for reflecting secondary electrons generated by the EUV resist back towards the EUV resist.

In some embodiments, forming the electron reflector layer comprises providing an electron reflector precursor to the reaction chamber; and, generating a plasma.

In some embodiments, the plasma is generated in the reaction chamber.

In some embodiments, the plasma is provided in a plurality of pulses.

In some embodiments, a method as described herein further comprises a step of exposing the EUV resist to EUV radiation through a mask.

In some embodiments, a method as described herein further comprises a step of forming an electron generation layer on the electron reflector layer, and the EUV resist is formed on the electron generation layer.

In some embodiments, the electron reflector precursor comprises a metal selected from Al and Mg.

In some embodiments, a method as described herein further comprises providing an electron reflector layer reactant, the electron reflector layer reactant being selected from an oxygen reactant and a nitrogen reactant.

Systems as described herein comprise an electron reflector layer reaction chamber that is constructed and arranged for forming an electron reflector layer on a substrate. In some embodiments, a system as described herein comprises an electron reflector layer reaction chamber being constructed and arranged for forming an electron reflector layer on a substrate; an EUV resist reaction chamber being constructed and arranged for forming an EUV resist on the electron reflector layer; and, a wafer handling robot being constructed and arranged for moving the substrate from the electron reflector layer reaction chamber to the EUV resist reaction chamber.

In some embodiments, a system as described herein further comprises a controller, the controller being constructed and arranged for causing the system to carry out a method as described herein.

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

### BRIEF DESCRIPTION OF THE DRAWING FIGURES

FIGS. 1-4 show structures according to embodiments of the present disclosure.

FIG. 5 shows an embodiment of a method (500) according to the present disclosure.

FIG. 6 shows an embodiment of a system (600) according to the present disclosure.

FIG. 7 shows an embodiment of a structure according to an embodiment of the present disclosure.

FIG. 8 shows an embodiment of a reactor according to the present disclosure.

FIGS. 9 and 10 show exemplary ALD pulsing schemes.

FIG. 11 illustrates a system (1100) in accordance with exemplary embodiments of the disclosure.

FIG. 12 illustrates a sub-system (1200) in accordance with exemplary embodiments of the disclosure.

FIG. 13 illustrates a sub-system (1300) in accordance with exemplary embodiments of the disclosure.

FIG. 14 illustrates a sub-system (1400) in accordance with exemplary embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas. Precursors and reactants can be gasses. Exemplary seal gasses include noble gasses, nitrogen, and the like. In some cases, the term “precursor” can refer to a compound that participates in the chemical reaction that produces another compound, and particularly to a compound that constitutes a film matrix or a main skeleton of a film; the term “reactant” can be used interchangeably with the term precursor.

As used herein, the term “film” and/or “layer” can refer to any continuous or non-continuous structure and material, such as material deposited by the methods disclosed herein. For example, a film and/or layer can include two-dimensional materials, three-dimensional materials, nanoparticles, partial or full molecular layers or partial or full atomic layers or clusters of atoms and/or molecules. A film or layer may comprise, or may consist at least partially of, a plurality of dispersed atoms on a surface of a substrate and/or may be or may become embedded in a substrate and/or may be or may become embedded in a device manufactured on that substrate. A film or layer may comprise material or a layer with pinholes and/or isolated islands. A film or layer may be at least partially continuous. A film or layer may be patterned, e.g. subdivided, and may be comprised in a plurality of semiconductor devices. A film or layer may be selectively grown on some parts of a substrate, and not on others.

The term “deposition process” as used herein can refer to the introduction of precursors (and/or reactants) into a reaction chamber to deposit a layer over a substrate. “Cyclical deposition processes” are examples of “deposition processes”.

The term “cyclic deposition process” or “cyclical deposition process” can refer to the sequential introduction of precursors (and/or reactants) into a reaction chamber to deposit a layer over a substrate and includes processing techniques such as atomic layer deposition (ALD), cyclical chemical vapor deposition (cyclical CVD), and hybrid cyclical deposition processes that include an ALD component and a cyclical CVD component.

The term “atomic layer deposition” can refer to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas(es). A pulse can comprise exposing a substrate to a precursor or reactant. This can be done, for example, by introducing a precursor or reactant to a reaction chamber in which the substrate is present. Additionally or alternatively, exposing the substrate to a precursor can comprise moving the substrate to a location in a substrate processing system in which the reactant or precursor is present.

Generally, for ALD processes, during each cycle, a precursor is introduced into a reaction chamber and is chemisorbed onto a deposition surface (e.g., a substrate surface that can include a previously deposited material from a previous ALD cycle or other material) and forming about a monolayer or sub-monolayer of material that does not readily react with additional precursor (i.e., a self-limiting reaction). Thereafter, a reactant (e.g., another precursor or reaction gas) may subsequently be introduced into the process chamber for use in converting the chemisorbed precursor to the desired material on the deposition surface. The reactant can be capable of further reaction with the precursor. Purging steps can be utilized during one or more cycles, e.g., during each step of each cycle, to remove any excess precursor from the process chamber and/or remove any excess reactant and/or reaction byproducts from the reaction chamber.

As used herein, the term “purge” may refer to a procedure in which an inert or substantially inert gas is provided to a reaction chamber in between two pulses of gasses that react with each other. For example, a purge, e.g. using a noble gas, may be provided between a precursor pulse and a reactant pulse, thus avoiding or at least minimizing gas phase interactions between the precursor and the reactant. It shall be understood that a purge can be effected either in time or in space, or both. For example in the case of temporal purges, a purge step can be used e.g. in the temporal sequence of providing a first precursor to a reaction chamber, providing a purge gas to the reaction chamber, and providing a second precursor to the reaction chamber, wherein the substrate on which a layer is deposited does not move. For example in the case of spatial purges, a purge step can take the following form: moving a substrate from a first location to which a first precursor is continually supplied, through a purge gas curtain, to a second location to which a second precursor is continually supplied.

As used herein, a “precursor” includes a gas or a material that can become gaseous and that can be represented by a chemical formula that includes an element which may be incorporated during a deposition process as described herein.

The term “oxygen reactant” can refer to a gas or a material that can become gaseous and that can be represented by a chemical formula that includes oxygen. In some cases, the chemical formula includes oxygen and hydrogen.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like.

As used herein, the term “comprising” indicates that certain features are included, but that it does not exclude the presence of other features, as long as they do not render the claim or embodiment unworkable. In some embodiments, the term “comprising” includes “consisting”. As used herein, the term “consisting” indicates that no further features are present in the apparatus/method/product apart from the ones following said term. When the term “consisting” is used referring to a chemical compound, it indicates that the chemical compound only contains the components which are listed.

In this disclosure, any defined meanings do not necessarily exclude ordinary and customary meanings, in some embodiments.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

The illustrations presented herein are not meant to be actual views of any particular material, structure, or device, but are merely idealized representations that are used to describe embodiments of the disclosure.

The term “dose” as used herein can refer to an amount of photon energy provided to a substrate per unit area, or in other terms, to the photon flux (number of photons per unit time per unit space) multiplied by the photon energy and exposure time.

Methods and structures as disclosed herein can advantageously reduce the dose required during exposure of EUV resists. An EUV resist layer may include any suitable resist, such as molecular, metal oxide, or chemically amplified resist. It shall be understood that the resists can be formed using any suitable deposition technique, including chemical vapor deposition (CVD), plasma-enhanced chemical vapor deposition (PECVD), atomic layer deposition (ALD), and plasma-enhanced atomic layer deposition (PEALD).

In particular, presently described methods and structures can avoid or at least reduce loss of randomly moving electrons are to the substrate. Presently disclosed methods and systems specifically relate to secondary electron reflector layers which can suitably reflect secondary electrons to an EUV resist. Those reflected secondary electrons would be lost to the substrate in absence of the secondary electron reflector layer.

Additionally or alternatively, presently described methods and structures can reduce the EUV dose needed for full exposure of resist compared to methods and structures that do not employ the teachings disclosed herein.

Additionally or alternatively, presently described methods and structures can provide low-cost patterning stacks.

Additionally or alternatively, presently described methods and structures can provide very thin patterning stacks.

Particularly described herein is a structure that can be advantageously employed during lithographical patterning of a substrate using electromagnetic radiation, particularly short wavelength electromagnetic radiation such as extreme ultraviolet (EUV) radiation.

A structure as described herein comprises a substrate, an electron reflector layer overlying the substrate, and an extreme ultraviolet (EUV) resist overlying the electron generation layer.

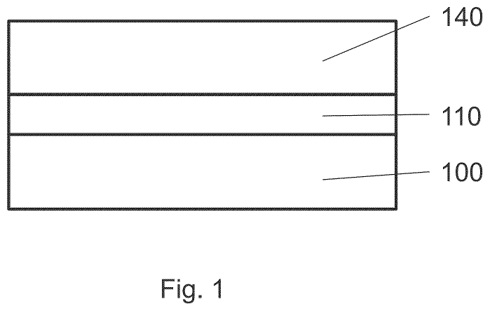

An embodiment of such a structure is described in FIG. 1. The structure of the embodiment of FIG. 1 particularly comprises a substrate (100), an electron reflector layer (110) overlying the substrate (100), and an EUV resist (140) overlying the electron reflector layer (110). Characteristic of such a structure is that the EUV resist (140) can be adjacent to the electron reflector layer (110), without any intervening secondary electron generation layer. For example, the EUV resist (140) can be directly deposited on the electron reflector layer (110). Alternatively, a glue layer may be directly deposited on the electron reflector layer and EUV resist may be directly deposited on the glue layer. Such structures, which can omit a specific secondary electron layer, can be advantageously used with metalorganic resist (MOR PR). Indeed, MOR PR comprises elements that effectively absorb EUV radiation, therefore obviating the need for additional secondary electron generation layers.

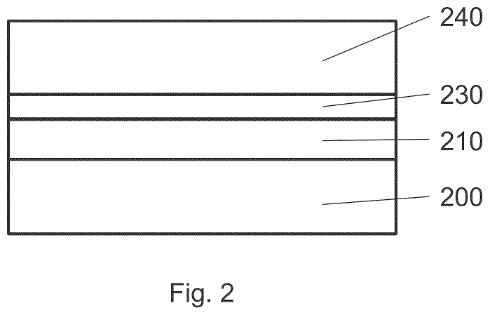

Of course, a structure as described herein can comprise further layers. For example, the structure shown in the embodiment of FIG. 2 further comprises a glue layer (230) that is constructed and arranged for enhancing adhesion between two adjacent layers. In particular, the structure shown in the embodiment of FIG. 2 comprises a substrate (200), a secondary electron reflecting layer (210) overlying the substrate (200), a glue layer (230) overlying the reflecting layer (210), and an EUV resist (240) overlying the glue layer (230). Such structures, which can omit a specific secondary electron layer, can be advantageously used with metalorganic resist (MOR PR).

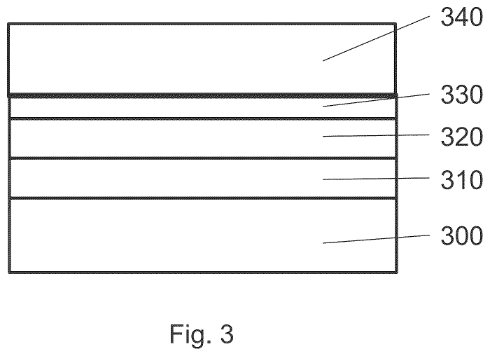

Of course, a structure as described herein can comprise even additional layers. For example, the structure shown in the embodiment of FIG. 3 further comprises a secondary electron generation layer (320) that can be constructed and arranged for absorbing EUV light and generating secondary electrons. In particular, the structure shown in the embodiment of FIG. 3 comprises a substrate (300), a secondary electron reflecting layer (310) overlying the substrate (300), a secondary electron generation layer (320) overlying the secondary electron reflecting layer (310), a glue layer (330) overlying the secondary electron generating layer (320), and an EUV resist (340) overlying the glue layer (330). Such structures, which include a specific secondary electron generation layer, can be advantageously used with chemically amplified resist (CAR). Indeed, CAR can have relatively low EUV absorption, therefore making the inclusion of a specific secondary electron generation layer between the secondary electron reflecting layer and the EUV resist advantageous.

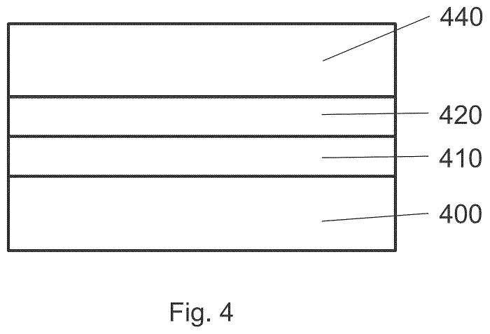

Of course, a structure as described herein can have other configurations still. For example, the structure shown in the embodiment of FIG. 4 comprises a secondary electron reflection layer (410), a secondary electron generation layer (420), and no glue layer. In particular, the structure when in the embodiment of FIG. 4 comprises a substrate (400), a secondary electron reflecting layer (410) overlying the substrate (400), a secondary electron generation layer (420) overlying the secondary electron reflecting layer (410), and an EUV resist (440) overlying the secondary electron generation layer (420). Such structures, which include a specific secondary electron generation layer, can be advantageously used with chemically amplified resist (CAR).

In some embodiments, a structure as described herein can comprise a substrate, an electron reflector layer, and an extreme ultraviolet (EUV) resist. The electron reflector layer can overly the substrate. The extreme ultraviolet (EUV) resist can overly the electron generation layer. IN some embodiments, one or more further layers can be positioned between the electron reflector layer and the EUV resist. Exemplary further layers include glue layers and secondary electron generating layers. The EUV resist can be constructed and arranged for absorbing EUV radiation and generating secondary electrons. The electron reflector layer can be constructed and arranged for reflecting secondary electrons generated by the EUV resist back towards the EUV resist.

Secondary electron reflection layers can suitably reflect secondary electrons generated in overlying layers back to those overlying layers. Examples of overlying layers include glue layers, secondary electron generation layers, and EUV resist.

In some embodiments, a secondary electron reflection layer as described herein can comprise at least one of aluminum and magnesium. In some embodiments, a secondary electron reflection layer as described herein comprises a material selected from aluminum oxide, aluminum nitride, aluminum oxynitride, and magnesium aluminum oxide. Aluminum oxide can comprise Al₂O₃. Aluminum nitride can comprise AlN. Aluminum magnesium oxide can comprise MgAl₂O₄. In some embodiments, the electron reflection layer comprises at least one of aluminum and magnesium. In some embodiments, the electron reflection layer comprises an electron reflection material selected from the list consisting of Al₂O₃, AlN, AlON, and MgAl₂O₄. It shall be understood that Al₂O₃ stands for aluminum oxide, AlN stands for aluminum nitride, AlON stands for aluminum oxynitride, and MgAl₂O₄ stands for magnesium aluminum oxide. These materials may be stoichiometric, close to stoichiometric, or non-stoichiometric.

In some embodiments, the secondary electron reflector layer comprises a barium-containing material such as barium oxide.

In some embodiments, the secondary electron reflector layer comprises a nitride, an oxide, or an oxynitride of an element selected from aluminum, magnesium, and barium.

In some embodiments, the secondary electron reflector layer has a thickness of at least 1 nm to at most 10 nm, such as a thickness from at least 1 to at most 2 nm, or a thickness of at least 2 to at most 5 nm, or a thickness of at least 5 to at most 10 nm.

In some embodiments, the secondary electron reflector layer comprises nitrogen. Without the present disclosure being limited by any particular theory or mode of operation, it is believed that introducing nitrogen in the reflector layer, we can reduce the electron affinity and increase electron escape probability which results in producing more secondary electrons.

In some embodiments, the secondary electron reflector layer comprises one or more of a nitrite, oxynitrate, and a ternary material. In some embodiments, the secondary electron reflector layer comprises one or more of an oxide, a nitride, and an oxynitride. Without the present disclosure being limited by any particular theory or mode of operation, it is believed that thusly, we can change the surface of the layer and improve the interface between layers, resulting in a higher electron movement.

In some embodiments, a structure according to an embodiment according to the present disclosure further comprises an electron generation layer. In some embodiments, the electron generation layer is positioned between the electron reflector layer and the EUV resist. Suitable secondary electron generation layers include metal oxides such as antimony oxide and tin oxide.

In some embodiments, a secondary electron generation layer as described herein can comprise one or more elements selected from magnesium, tin, and aluminum. For example, a secondary electron generation layer as described herein can comprise one or more materials selected from the list consisting of magnesium oxide, antimony oxide, and tin oxide. Magnesium oxide can comprise MgO. Antimony oxide can comprise SbO. Tin oxide can comprise SnO, i.e. tin(II) oxide.

In some embodiments, the secondary electron generation layer comprises a chalcogenide such as sulfur, selenium, or tellurium. For example, the secondary electron generation layer can comprise a metal chalcogenide such as one or more of MgS, SbS, SnS, MgSe, SbSe, SnSe, MgTe, SbTe, or SnTe.

In some embodiments, the EUV resist is selected from a metalorganic framework resist, a metal oxide resist, and a chemically amplified resist. The resist can be positive or negative tone.

In some embodiments, a structure as described herein can comprise a secondary electron reflection layer, an optional glue layer overlying the secondary electron reflection layer, and a metalorganic photoresist on the electron reflector layer or the glue layer.

In some embodiments, a structure as described herein can comprise a secondary electron reflection layer, a secondary electron generation layer on the secondary electron reflection layer, an optional glue layer on the secondary electron generation layer, and a chemically amplified photoresist on the electron reflector generation or the glue layer.

In some embodiments, a structure as described herein comprises a glue layer.

In some embodiments, the glue layer comprises silicon, oxygen, and carbon. In some embodiments, the glue layer can comprise silicon oxycarbide. In some embodiments, the glue layer can further comprise nitrogen. In some embodiments, the glue layer can comprise silicon oxycarbonitride. In some embodiments, the glue layer further comprises hydrogen. The glue layer can be formed using a thermal or a plasma vapor phase deposition process. For example, the glue layer can be formed by means of thermal or plasma-enhanced atomic layer deposition.

In some embodiments, the glue layer is positioned between the electron reflector layer and the EUV resist.

In some embodiments, the glue layer is positioned between the electron reflector layer and the EUV resist.

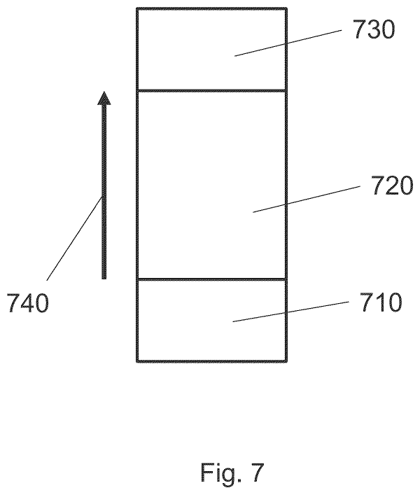

In some embodiments, at least one of the secondary electron reflection layer and the secondary electron generation layer comprises an oxygen gradient. In some embodiments, at least one of the secondary electron reflection layer and the secondary electron generation layer comprises a carbon gradient. An embodiment of such a structure is shown in FIG. 7. In particular,

FIG. 7 shows a substrate (710) on which a layer (720) is formed. The layer (720) can be a secondary electron reflector layer or a secondary electron generation layer, for example a layer comprising one or more of antimony oxide, tin oxide, and magnesium oxide. An EUV resist (730) is formed on the layer (720) The layer (720) comprises an element that is selected from carbon, oxygen, and nitrogen. The concentration of the element can increase in the layer (720) from the substrate (710) towards the EUV resist (730), as symbolically indicated by a gradient arrow (740). In some embodiments, the carbon content of the layer (720) increases from the substrate (710) towards the EUV resist (730). In some embodiments, the oxygen content of the layer (720) increases from the substrate (710) towards the EUV resist (730). In some embodiments, the nitrogen content of the layer (720) increases from the substrate (710) towards the EUV resist (730). Without restricting the present disclosure to any particular theory or mode of operation, it is believed that such concentration gradients can enhance the transfer of secondary electrons between adjacent layers.

A secondary electron reflector layer as described herein can be formed using any suitable deposition method. Suitable deposition methods include vapor phase deposition methods such as thermal and plasma-enhanced atomic layer deposition and chemical vapor deposition.

The new stacked layer would be deposited by using ALD/CVD mechanisms and machinery as it needs to be very thin and smooth.

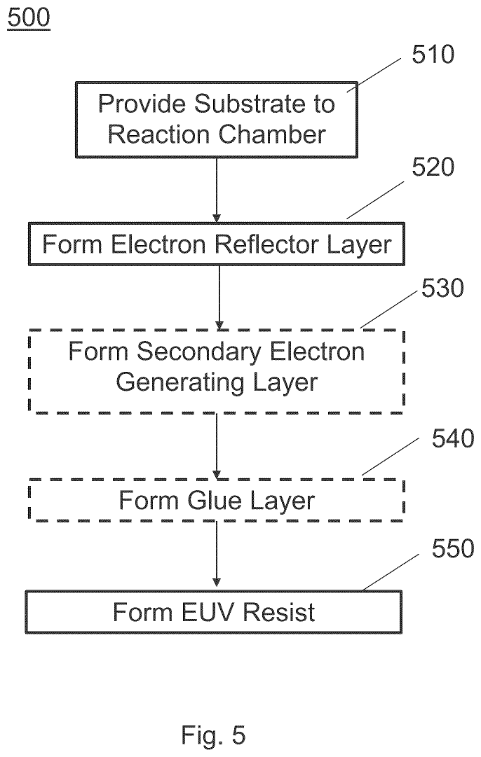

Further described herein is a method than can be advantageously employed for forming a structure as described herein. With reference to FIG. 5, an embodiment of a method (500) as described herein comprises a step (510) of providing a substrate to a reaction chamber. The method (500) further comprises a step (520) forming an electron reflector layer on the substrate. Optionally, the method (500) can further comprise a step (530) of forming a secondary electron generating layer on the substrate. Optionally, the method (500) can further comprise a step (540) of forming a glue layer on the substrate. The method (500) further comprises a step (550) of forming an EUV resist on the substrate. The EUV resist can be suitably constructed and arranged for absorbing EUV radiation and generating secondary electrons. The electron reflector layer can be suitably constructed and arranged for reflecting secondary electrons generated by the EUV resist back towards the EUV resist.

In some embodiments, the secondary electron generation layer is particularly formed on the secondary electron reflector layer.

In some embodiments, the glue layer is particularly formed on the secondary electron reflector layer.

In some embodiments, the EUV resist is particularly formed on the secondary electron reflector layer.

In some embodiments, the EUV resist is particularly formed on the secondary electron generation layer.

In some embodiments, the electron reflector precursor can comprise an element selected from aluminum, magnesium, and barium. In some embodiments, the electron reflector precursor comprise an element selected from Al and Mg. Suitably, when the electron reflector precursor comprises aluminum, an electron reflector layer comprising an aluminum-containing material such as aluminum oxide can be formed. Suitably, when the electron reflector precursor comprises magnesium, an electron reflector layer comprising a magnesium-containing material such as magnesium oxide can be formed. Suitably, when the electron reflector precursor comprises barium, an electron reflector layer comprising a barium-containing material such as barium oxide can be formed.

In some embodiments, forming the electron reflector layer can comprise providing an electron reflector reactant, in particular forming the electron reflector layer can comprise at least one of contacting the substrate with an electron reflector layer reactant and providing the electron reflector layer reactant to a reaction chamber comprising said substrate. Suitable electron reflector layer reactants include oxygen reactants and nitrogen reactants. Suitable oxygen reactants include O₂, O₃, and H₂O. Suitable nitrogen reactants include N₂and NH₃.

In some embodiments, forming the electron reflector layer comprises providing an electron reflector precursor to the reaction chamber; and, generating a plasma.

In some embodiments, the plasma is generated in the reaction chamber. Thus in some embodiments, the plasma can be a direct plasma. The plasma can be provided continuously or in a plurality of pulses.

In some embodiments, forming at least one of the secondary electron reflector layer and the secondary electron generation layer comprises executing a cyclical deposition process. The cyclical deposition process comprises executing a plurality of deposition cycles. Ones from the plurality of deposition cycles comprise executing a precursor pulse and a reactant pulse. In some embodiments, consecutive precursor pulses and reactant pulses can be separated by purges. A precursor pulse comprises contacting the substrate with a precursor. A reactant pulse comprises contacting the substrate with a reactant.

In some embodiments, a method as described herein further comprises a step of exposing the EUV resist to EUV radiation through a mask.

In some embodiments, a method as described herein further comprises a step of forming an electron generation layer on the electron reflector layer, and the EUV resist can be formed on the electron generation layer.

Suitable aluminum precursors include aluminum alkyls such as trimethylaluminum, triethylaluminum, and tripropylaluminum. Suitably, such precursors can be employed for forming electron reflector layers that comprise aluminum oxide. In particular, such precursors can be used for forming aluminum oxide using an ALD sequence with alternating aluminum precursor pulses and oxygen reactant pulses. Suitable oxygen reactants include H₂O. Suitable substrate temperatures can be about 300° C.

Suitable aluminum precursors include aluminum alkylamines such as tris(dimethylamido)aluminum, tris(ethylmethylamido)aluminum, and tris(diethylamido)aluminum. Suitably, such precursors can be employed for forming electron reflector layers that comprise aluminum nitride. For example, thin films of aluminum nitride (AlN) and oxynitride (AlON) can be deposited by ALD in the substrate temperature range from 170 to 290° C. (e.g. substrate temperature 200-230° C.). An aluminum alkylamine such as tris(dimethylamido) aluminum and a nitrogen reactant such as ammonia may be used as precursors for the atomic layer deposition of aluminum nitride (AlN).

Suitable magnesium precursors include magnesium pi complexes such as bis-(cyclopentadienyl) magnesium, bis-(methylcyclopentadienyl) magnesium, and bis-(ethylcyclopentadienyl) magnesium. Suitably, such precursors can be employed for forming electron reflector layers that comprise magnesium oxide.

Suitable antimony precursors include antimony alkylsilyls such as tris-(trimethylsilyl) antimony and tris-(triethylsilyl) antimony.

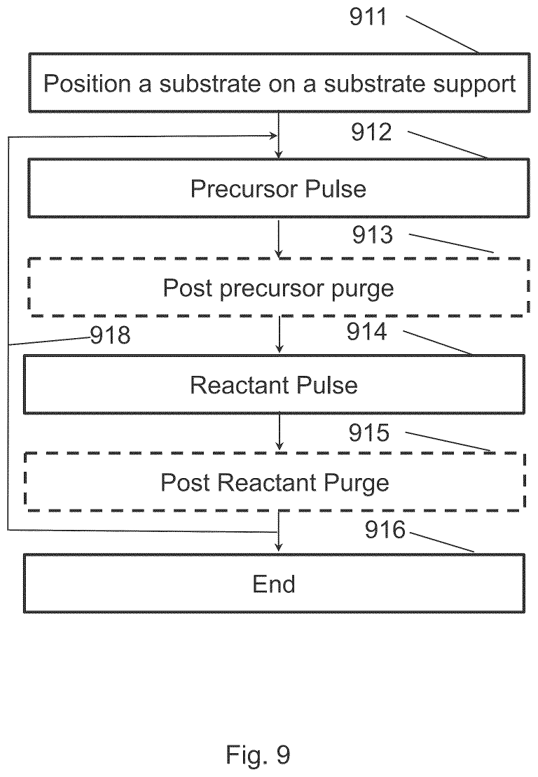

An exemplary ALD pulsing scheme is shown in FIG. 9. Such a pulsing scheme can be suitable used for forming binary materials such as magnesium oxide. In particular, the embodiment of FIG. 9 comprises a step (911) of positioning a substrate on a substrate support, after which a plurality of deposition cycles (918) are executed. Ones from the plurality of deposition cycles (918) comprise a precursor pulse (912) and a reactant pulse (914). Optionally, precursor pulses (912) can be followed by post precursor purges (913). Optionally, reactant pulses (914) can be followed by post reactant purges (915). After a suitable amount of deposition cycles (918) have been executed, a layer has been formed on the substrate, and the method ends (916).

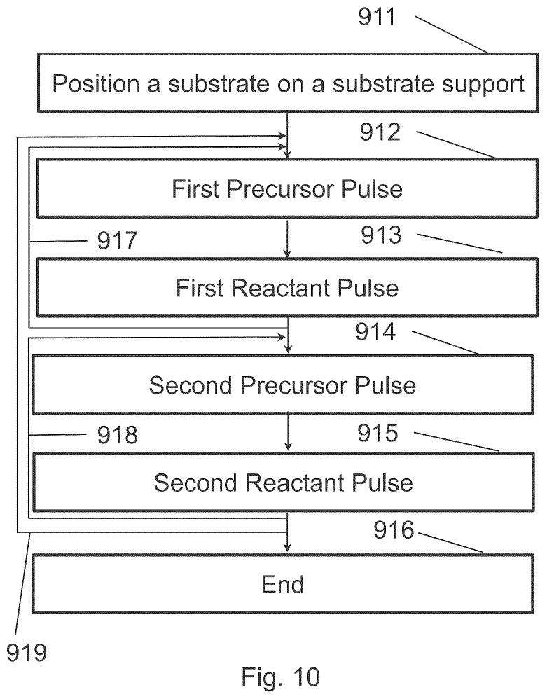

Another exemplary ALD pulsing scheme is shown in FIG. 10. Such a pulsing scheme can be advantageously used for forming ternary materials such as magnesium aluminum oxide (MgAl₂O₄). In particular, the embodiment of FIG. 10 comprises a step (1011) of positioning a substrate on a substrate support, after which a plurality of deposition cycles (1019) are executed. Ones from the plurality of deposition cycles (1018) comprise a first sub cycle (1017) and a second sub cycle (1018). Optionally, the first sub cycle (1017), can be repeated one or more times. Optionally, the second sub cycle (1018) can be repeated one or more times. The first sub cycle (1017) comprises a first precursor pulse (1012) and a first reactant pulse (1013). The first precursor pulse (1012) comprises exposing the substrate to a first precursor. The first reactant pulse (1013) comprises exposing the substrate to a first reactant (1014). The second sub cycle comprises a second precursor pulse (1014) and a second reactant pulse (1015). The second precursor pulse (1014) comprises exposing the substrate to a second precursor. The second reactant pulse (1015) comprises exposing the substrate to a second reactant (1015). After a suitable amount of deposition cycles (1018) have been executed, a layer has been formed on the substrate, and the method ends (1016). Subsequent pulses may be optionally separated by a purge.

In some embodiments, the first precursor and the second precursor are different. In some embodiments, the first reactant and the second reactant are different. For example, in order to form magnesium aluminum oxide, the first precursor may be a magnesium precursor, and the first and second reactants may be oxygen reactants.

For example, a MgAl₂O₄ layer can be formed using atomic layer deposition using an aluminum precursor comprising an aluminum alkyl such as trimethylaluminum, a magnesium pi complex such as bis-(cyclopentadienyl) magnesium as the magnesium precursor, and an oxygen reactant such as water. For example, the ALD sequence can comprise a plurality of super cycles. A super cycle can comprise one or more, such as 1, 2, 3, 4, or 5 magnesium sub cycles. A super cycle can comprise one or more, such as 1, 2, 3, 4, or 5 aluminum sub cycles. A magnesium sub cycle comprises an magnesium pulse that comprises contacting the substrate with the magnesium precursor, and an oxygen pulse that comprises contacting the substrate with the oxygen reactant. An aluminum sub cycle comprises an aluminum pulse that comprises contacting the substrate with the aluminum precursor, and an oxygen pulse that comprises contacting the substrate with the oxygen reactant. Subsequent pulses can be separated by purges. Suitably, a noble gas such as argon or N₂ can be used as a purge gas. Suitable substrate temperatures can include the range of 160-190° C. A precursor such as trimethylaluminum can be kept at room temperature. A precursor such as bis-(cyclopentadienyl) magnesium can be stored at an elevated temperature above room temperature such as about 100° C.

Suitable tin precursors include tin alkylamines such as tetrakis(dimethylamido)tin, tetrakis(ethylmethylamido)tin, and tetrakis(diethylamido)tin.

Suitable reactants include oxygen reactants such as O₂, O₃, and H₂O and nitrogen reactants such as NH₃. In some embodiment, the reactants can comprise a chalcogenide such as sulfur, selenium, or tellurium. Suitable sulfur reactants include H₂S. Suitable selenium reactants include H₂Se. Suitable tellurium reactants include H₂Te.

In some embodiments, the secondary electron reflection layer can be formed using a cyclical deposition process such as atomic layer deposition (ALD). For example, the secondary electron reflection layer can comprise ALD-deposited MgAl₂O₄, which can be deposited using the following procedure: trimethylaluminum (TMA) stored at ambient temperature can be used as an aluminum precursor, bis-(cyclopentadienyl) magnesium (MgCp₂) stored at 100° C. can be used as a magnesium precursor, and H₂O can be used as an oxygen reactant. The ALD process can comprise subsequent cycles, with each cycle comprising at least one aluminum precursor pulse, at least one magnesium precursor pulse, and at least one oxygen reactant pulse. In some embodiments, a cycle can comprise an aluminum precursor pulse followed by an oxygen reactant pulse, followed by a magnesium precursor pulse, followed by an oxygen reactant pulse. Suitably, purges, e.g. using N₂ as a purge gas, can be used to separate subsequent pulses. During the cyclical deposition process, the substrate can be suitably maintained at a temperature of at least 160° C. to at most 190° C.

In some embodiments, the secondary electron generation layer can be formed using a cyclical deposition process such as atomic layer deposition (ALD). For example, a cyclical deposition process can be executed by alternatingly contacting the substrate with a metal precursor and exposing the substrate to a direct plasma. Suitable metal precursors include antimony precursors and tin precursors as disclosed herein. Suitable plasmas include noble gas plasmas such as argon plasmas, and reducing plasmas such as Ar/H₂ plasmas. Optionally, a glue layer can be formed between the secondary electron generation layer and the EUV resist.

In an exemplary embodiment, a structure as described herein can comprise a secondary electron reflection layer, a secondary electron generation layer, and a chemically amplified resist. The secondary electron reflector layer can have a thickness of less than 5 nanometers, e.g. a thickness of 2 nanometers. The secondary electron reflection layer can comprise, for example, one or more of AL₂O₃, AlN, AlON, and MgAl₂O₄. The secondary electron generation layer can comprise one or more metal oxides such as antimony oxide, tin oxide, or magnesium oxide.

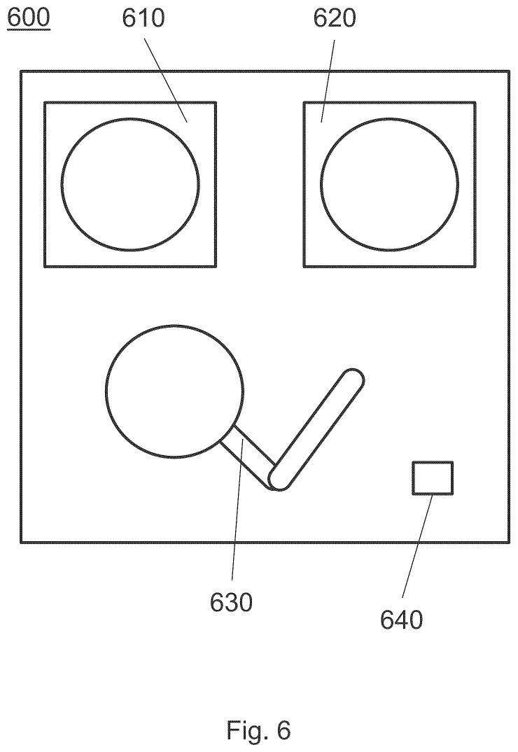

Referring to FIG. 6, further described herein is a system (600) that comprises an electron reflector layer reaction chamber (610), an EUV resist reaction chamber (620), and a wafer handling robot (630). The electron reflector layer reaction chamber (610) is constructed and arranged for forming an electron reflector layer on a substrate by means of a method as described herein. The EUV resist reaction chamber (620) is constructed and arranged for forming an EUV resist on the electron reflector layer. The wafer handling robot (630) can be constructed and arranged for moving the substrate from the electron reflector layer reaction chamber (610) to the EUV resist reaction chamber (620). The system (600) can further comprise a controller (640) which is constructed and arranged for causing the system to execute a method as described herein.

Of course, the system (600) can comprise further reaction chambers such as thermal or plasma-enhanced atomic layer deposition (ALD) reaction chambers and thermal or plasma-enhanced chemical vapor deposition (CVD) reaction chambers. The wafer handling robot (630) can be constructed and arranged for moving substrates between the various reaction chambers comprised in the system (630).

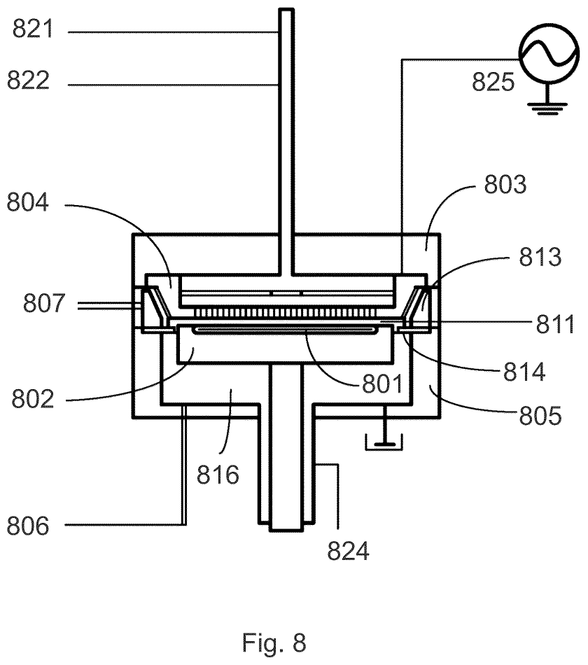

Layers formed in methods according to the present disclosure may be formed in any suitable apparatus, including in a reactor as shown in FIG. 8. Similarly, the presently provided structures or parts thereof may be manufactured in any suitable apparatus, including a reactor as shown in FIG. 8. FIG. 8 is a schematic view of a plasma-enhanced atomic layer deposition (PEALD) apparatus, desirably in conjunction with controls programmed to conduct the sequences described below, usable in some embodiments of the present disclosure. In this figure, by providing a pair of electrically conductive flat-plate electrodes (802,804) in parallel and facing each other in the interior (811) (reaction zone) of a reaction chamber (803), applying RF power (e.g. at 13.56 MHz and/or 27 MHz) from a power source (825) to one side, and electrically grounding the other side (812), a plasma is excited between the electrodes. A temperature regulator may be provided in a lower stage (802), i.e. the lower electrode. A substrate (801) is placed thereon and its temperature is kept constant at a given temperature. The upper electrode (804) can serve as a shower plate as well, and a reactant gas and/or a dilution gas, if any, as well as a precursor gas can be introduced into the reaction chamber (803) through a gas line (821) and a gas line (822), respectively, and through the shower plate (804). Additionally, in the reaction chamber (803), a circular duct (813) with an exhaust line (817) is provided, through which the gas in the interior (811) of the reaction chamber (803) is exhausted. Additionally, a transfer chamber (805) is disposed below the reaction chamber (803) and is provided with a gas seal line (824) to introduce seal gas into the interior (811) of the reaction chamber (803) via the interior (816) of the transfer chamber (805) wherein a separation plate (814) for separating the reaction zone and the transfer zone is provided. Note that a gate valve through which a wafer may be transferred into or from the transfer chamber (805) is omitted from this figure. The transfer chamber is also provided with an exhaust line (806). In some embodiments, forming the secondary electron reflection layer, optionally forming the secondary electron generation layer, optionally forming the glue layer, and forming the EUV resist are done in one and the same reaction chamber. In some embodiments, forming one or more of these layers are formed in separate reaction chambers comprised in one cluster system in which substrates are transferable from one reaction chamber to another without breaking vacuum.

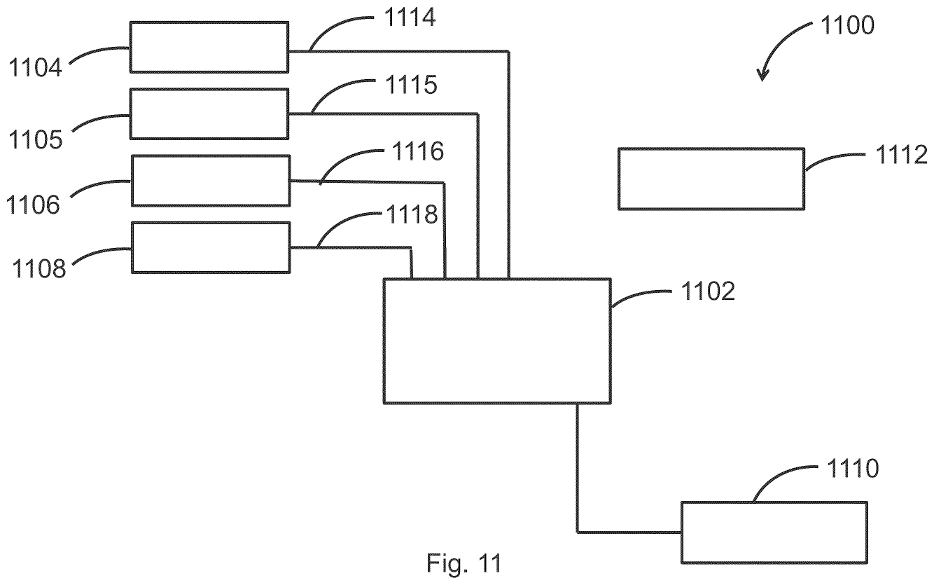

FIG. 11 illustrates a system (1100) in accordance with exemplary embodiments of the disclosure. The system (1100) can be used to perform a method as described herein and/or form a structure or device portion as described herein.

In the illustrated example, the system (1100) includes one or more reaction chambers (1102), a first precursor gas source (1104), a reactant gas source (1106), a purge gas source (1108), an exhaust (1110), and a controller (1112).

The reaction chamber (1102) can include any suitable reaction chamber, such as an ALD or CVD reaction chamber.

The aluminum precursor gas source (1104) can include a vessel and one or more precursors as described herein-alone or mixed with one or more carrier (e.g., noble) gases. The transition metal precursor gas source (1106) can include a vessel and one or more reactants as described herein-alone or mixed with one or more carrier gases. The purge gas source (1108) can include one or more noble gases as described herein. Although illustrated with four gas sources (1104)-(1108), the system (1100) can include any suitable number of gas sources. The gas sources (1104)-(1108) can be coupled to reaction chamber (1102) via lines (1114)-(1118), which can each include flow controllers, valves, heaters, and the like.

The exhaust (1110) can include one or more vacuum pumps.

The controller (1112) includes electronic circuitry and software to selectively operate valves, manifolds, heaters, pumps and other components included in the system (1100). Such circuitry and components operate to introduce precursors and purge gases from the respective sources (1104)-(1108). The controller (1112) can control timing of gas pulse sequences, temperature of the substrate and/or reaction chamber, pressure within the reaction chamber, and various other operations to provide proper operation of the system (1100). The controller (1112) can include control software to electrically or pneumatically control valves to control flow of precursors, reactants and purge gases into and out of the reaction chamber (1102). The controller (1112) can include modules such as a software or hardware component, e.g., a FPGA or ASIC, which performs certain tasks. A module can advantageously be configured to reside on the addressable storage medium of the control system and be configured to execute one or more processes.

Other configurations of the system (1100) are possible, including different numbers and kinds of precursor and reactant sources and purge gas sources. Further, it will be appreciated that there are many arrangements of valves, conduits, precursor sources, and purge gas sources that may be used to accomplish the goal of selectively feeding gases into the reaction chamber (1102). Further, as a schematic representation of a system, many components have been omitted for simplicity of illustration, and such components may include, for example, various valves, manifolds, purifiers, heaters, containers, vents, and/or bypasses.

During operation of the reactor system (1100), substrates, such as semiconductor wafers (not illustrated), are transferred from, e.g., a substrate handling system to the reaction chamber (1102). Once substrate(s) are transferred to the reaction chamber (1102), one or more gases from the gas sources (1104)-(1108), such as precursors, reactants, carrier gases, and/or purge gases, are introduced into the reaction chamber (1102).

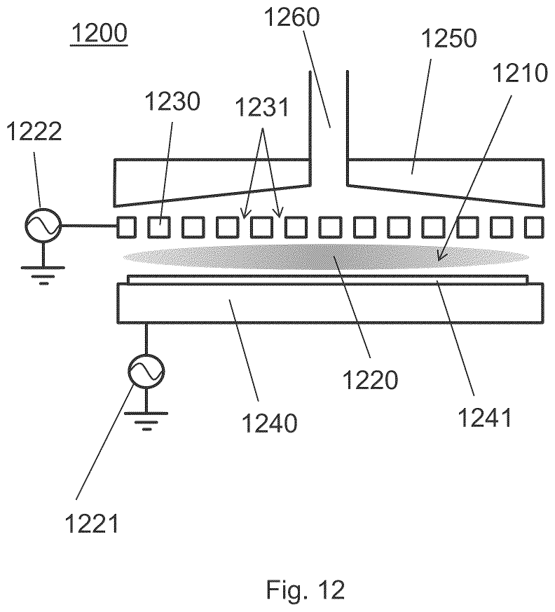

FIG. 12 shows a schematic representation of an embodiment of a sub-system (1200) as described herein. It can be used, for example, for forming at least one of a secondary electron reflection layer, a secondary electron generation layer, a glue layer, and an EUV resist. Additionally or alternatively, it can be employed for etching one or more of a gap filling fluid and a material layer. The sub-system (1200) comprises a reaction chamber (1210) in which a plasma (1220) is generated. In particular, the plasma (1220) is generated between a showerhead injector (1230) and a substrate support (1240). This is a direct plasma configuration employing a capacitively coupled plasma.

In the configuration shown, the sub-system (1200) comprises two alternating current (AC) power sources: a high frequency power source (1221) and a low frequency power source (1222). In the configuration shown, the high frequency power source (1221) supplies radio frequency (RF) power to the showerhead injector, and the low frequency power source (1222) supplies an alternating current signal to the substrate support (1240). The radio frequency power can be provided, for example, at a frequency of 13.56 MHz or higher, e.g. at a frequency of at least 100 kHz to at most 50 MHz, or at a frequency of at least 50 MHz to at most 100 MHz, or at a frequency of at least 100 MHz to at most 200 MHz, or at a frequency of at least 200 MHz to at most 500 MHz, or at a frequency of at least 500 MHz to at most 1000 MHz, or at a frequency of at least 1000 MHz to at most 2000 MHz. The low frequency alternating current signal can be provided, for example, at a frequency of 2 MHz or lower, such as at a frequency of at least 100 kHz to at most 200 kHz, or at a frequency of at least 200 kHz to at most 500 kHz, or at a frequency of at least 500 kHz to at most 1000 kHz, or at a frequency of at least 1000 kHz to at most 2000 kHz. Process gas comprising precursor, reactant, or both, is provided through a gas line (1260) to a conical gas distributor (1250). The process gas then passes through holes (1231) in the showerhead injector (1230) to the reaction chamber (1210).

Whereas the high frequency power source (1221) is shown as being electrically connected to the showerhead injector, and the low frequency power source (1222) is shown as being electrically connected to the substrate support (1240), other configurations are possible as well. For example, in some embodiments (not shown), both the high frequency power source and the low frequency power source can be electrically connected to the showerhead injector; or both the high frequency power source and the low frequency power source can be electrically connected to the substrate support; or the high frequency power source can be electrically connected to the substrate support, and the low frequency power source can be electrically connected to the showerhead injector.

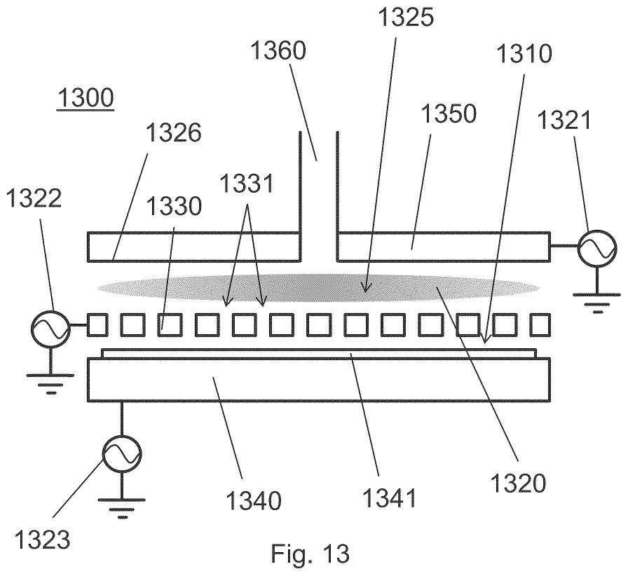

FIG. 13 shows a schematic representation of another embodiment of a sub-system (1300) as described herein It can be used, for example, for forming at least one of a secondary electron reflection layer, a secondary electron generation layer, a glue layer, and an EUV resist. The configuration of FIG. 13 can be described as an indirect plasma system. The sub-system (1300) comprises a reaction chamber (1310) which is separated from a plasma generation space (1325) in which a plasma (1320) is generated. In particular, the reaction chamber (1310) is separated from the plasma generation space (1325) by a showerhead injector, and the plasma (1320) is generated between the showerhead injector (1330) and a plasma generation space ceiling (1326).

In the configuration shown, the sub-system (1300) comprises three alternating current (AC) power sources: a high frequency power source (1321) and two low frequency power sources (1322,1323): a first low frequency power source (1322) and a second low frequency power source (1323). In the configuration shown, the high frequency power source (1321) supplies radio frequency (RF) power to the plasma generation space ceiling, the first low frequency power source (1322) supplies an alternating current signal to the showerhead injector (1330), and the second low frequency power source (1323) supplies an alternating current signal to the substrate support (1340). A substrate (1341) is provided on the substrate support (1340). The radio frequency power can be provided, for example, at a frequency of 13.56 MHz or higher. The low frequency alternating current signal of the first and second low frequency power sources (1322,1323) can be provided, for example, at a frequency of 2 MHz or lower.

Process gas comprising precursor, reactant, or both, is provided through a gas line (1360) that passes through the plasma generation space ceiling (1326), to the plasma generation space (1325). Active species such as ions and radicals generated by the plasma (1325) from the process gas pass through holes (1331) in the showerhead injector (1330) to the reaction chamber (1310).

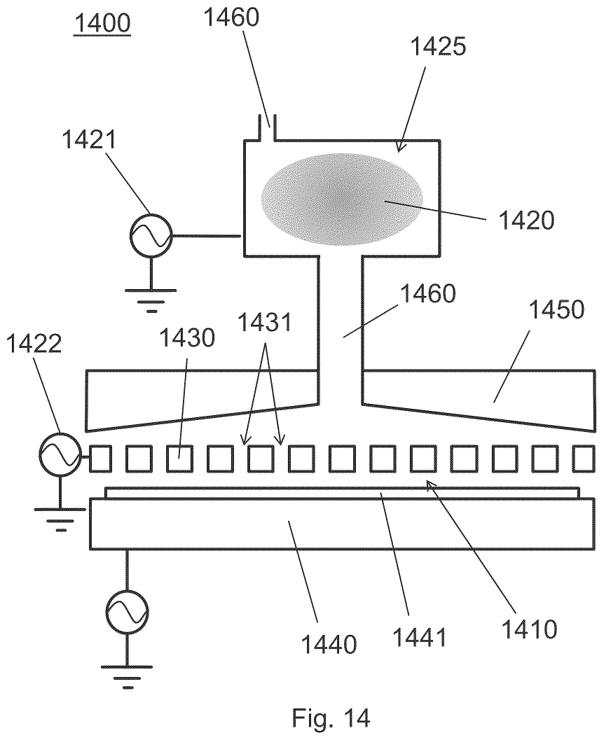

FIG. 14 shows a schematic representation of another embodiment of a sub-system (1400) as described herein. It can be used, for example, for forming at least one of a secondary electron reflection layer, a secondary electron generation layer, a glue layer, and an EUV resist. The configuration of FIG. 14 can be described as a remote plasma system. The sub-system (1400) comprises a reaction chamber (1410) which is operationally connected to a remote plasma source (1425) in which a plasma (1420) is generated. Any sort of plasma source can be used as a remote plasma source (1425), for example an inductively coupled plasma, a capacitively coupled plasma, or a microwave plasma.

In particular, active species are provided from the plasma source (1425) to the reaction chamber (1410) via an active species duct (1460), to a conical distributor (1450), through holes (1431) in a shower plate injector (1430), to the reaction chamber (1410). Thus, active species can be provided to the reaction chamber in a uniform way.

In the configuration shown, the sub-system (1400) comprises three alternating current (AC) power sources: a high frequency power source (1421) and two low frequency power sources (1422,1423): a first low frequency power source (1422) and a second low frequency power source (1423). In the configuration shown, the high frequency power source (1421) supplies radio frequency (RF) power to the plasma generation space ceiling, the first low frequency power source (1422) supplies an alternating current signal to the showerhead injector (1430), and the second low frequency power source (1423) supplies an alternating current signal to the substrate support (1440). A substrate (1441) is provided on the substrate support (1440). The radio frequency power can be provided, for example, at a frequency of 13.56 MHz or higher. The low frequency alternating current signal of the first and second low frequency power sources (1422,1423) can be provided, for example, at a frequency of 2 MHz or lower.

In some embodiments (not shown), an additional high frequency power source can be electrically connected to the substrate support. Thus, a direct plasma can be generated in the reaction chamber.

Process gas comprising precursor, reactant, or both, is provided to the plasma source (1425) by means of a gas line (1460). Active species such as ions and radicals generated by the plasma (1425) from the process gas are guided to the reaction chamber (1410).

In an exemplary embodiment, a system comprising a plasma source such as a system according to any one FIGS. 12, 13, and 14 can be employed for forming a secondary electron reflector layer as described herein, by means of a plasma-enhanced atomic layer deposition process. A suitable plasma-enhanced atomic layer deposition process can be described with reference to any one of FIGS. 9 and 10, in which one or more of the reactant pulses can comprise generating a plasma, in which case active species can be formed from one or more reactants employed to which the substrate is exposed. Suitable plasmas employ plasma gasses such as N₂, NH₃, noble gasses such as Ar or He, O₂, and mixtures thereof. Suitable secondary electron layers formed by means of a plasma-enhanced atomic layer deposition process can comprise an aluminum-containing material such as Al₂O₃, AlN, AlON, and MgAl₂O₄. It shall be understood that AlON denote a non-stoichiometric oxynitride of aluminum. Suitable aluminum precursors for making such materials can comprise aluminum alkyls such as trimethylaluminum or aluminum alkylamines such as tris(methylamido)aluminum. Suitable magnesium precursors for making such materials include magnesium-pi complexes such as magnesocene (MgCp₂)

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

1. A structure comprising
a substrate;
an electron reflector layer overlying the substrate; and,
an extreme ultraviolet (EUV) resist overlying an electron generation layer;
wherein,
the EUV resist is constructed and arranged for absorbing EUV radiation and generating secondary electrons; and,
the electron reflector layer is constructed and arranged for reflecting secondary electrons generated by the EUV resist back towards the EUV resist.

2. The structure according to claim 1, wherein the electron reflection layer comprises at least one of aluminum and magnesium.

3. The structure according to claim 2, wherein the electron reflection layer comprises an electron reflection material selected from the list consisting of Al₂O₃, AlN, AlON, and MgAl₂O₄.

4. The structure according to claim 1, wherein the EUV resist is selected from a metalorganic framework resist, a metal oxide resist, and a chemically amplified resist.

5. The structure according to claim 1 further comprising a glue layer.

6. The structure according to claim 5, wherein the glue layer comprises silicon, oxygen, and carbon.

7. The structure according to claim 5, wherein the glue layer is positioned between the electron reflector layer and the EUV resist.

8. The structure according to claim 1 further comprising an electron generation layer.

9. The structure according to claim 1, wherein the electron generation layer is positioned between the electron reflector layer and the EUV resist.

10. The structure according to claim 9 further comprising a glue layer, wherein the glue layer is positioned between the electron reflector layer and the EUV resist.

11. A method comprising:
providing a substrate to a reaction chamber;
forming an electron reflector layer on the substrate;
optionally forming a secondary electron generating layer on the substrate;
optionally forming a glue layer on the substrate; and,
forming an EUV resist on the substrate;
wherein:
the EUV resist is arranged for absorbing EUV radiation and generating secondary electrons; and,
the electron reflector layer is constructed and arranged for reflecting secondary electrons generated by the EUV resist back towards the EUV resist.

12. The method according to claim 11, wherein forming the electron reflector layer comprises
providing an electron reflector precursor to the reaction chamber; and,
generating a plasma.

13. The method according to claim 12, wherein the plasma is generated in the reaction chamber.

14. The method according to claim 12, wherein the plasma is provided in a plurality of pulses.

15. The method according to claim 11 further comprising a step of exposing the EUV resist to EUV radiation through a mask.

16. The method according to claim 11 further comprising a step of forming an electron generation layer on the electron reflector layer, wherein the EUV resist is formed on the electron generation layer.

17. The method according to claim 12, wherein the electron reflector precursor comprises a metal selected from Al and Mg.

18. The method according to claim 12 further comprising providing an electron reflector layer reactant, the electron reflector layer reactant being selected from an oxygen reactant and a nitrogen reactant.

19. A system comprising
an electron reflector layer reaction chamber being constructed and arranged for forming an electron reflector layer on a substrate;
an EUV resist reaction chamber being constructed and arranged for forming an EUV resist on the electron reflector layer; and,
a wafer handling robot being constructed and arranged for moving the substrate from the electron reflector layer reaction chamber to the EUV resist reaction chamber.

20. The system according to claim 19 further comprising a controller, the controller being constructed and arranged for causing the system to carry out a method comprising
providing a substrate to a reaction chamber;
forming an electron reflector layer on the substrate;
optionally forming a secondary electron generating layer on the substrate;
optionally forming a glue layer on the substrate; and,
forming an EUV resist on the substrate;
wherein:
the EUV resist is arranged for absorbing EUV radiation and generating secondary electrons; and,
the electron reflector layer is constructed and arranged for reflecting secondary electrons generated by the EUV resist back towards the EUV resist.
